(19) United States
(12) Patent Application Publication
(10) Pub. No.: US 2026/0052645 A1
(43) Pub. Date: Feb. 19, 2026

(54) LIQUID-COOLING HEAT DISSIPATION PLATE HAVING WAVY FINS

(71) Applicant: AMULAIRE THERMAL TECHNOLOGY, INC., New Taipei City (TW)

(72) Inventors: MING-HSUAN CHANG, Taoyuan City (TW); CHUN-LUNG WU, New Taipei City (TW); TZE-YANG YEH, New Taipei City (TW)

(21) Appl. No.: 18/808,569

(22) Filed: Aug. 19, 2024

(51) Int. Cl. H05K 7/20

(52) U.S. Cl. CPC H05K 7/20263; H05K 7/20927

(57) ABSTRACT

A liquid-cooling heat dissipation plate includes multiple wavy fins and a heat dissipation plate body having first and second heat dissipation surfaces that are opposite to each other. The first heat dissipation surface is configured to be in contact with multiple chips, and the second heat dissipation surface is configured to be in contact with a cooling liquid. The wavy fins are formed on the second heat dissipation surface. The heat dissipation plate body is divided to have multiple heat dissipation areas. Each heat dissipation area is divided into an upstream area, a midstream area, and a downstream area according to a cooling-liquid flowing direction. An upstream fin wavelength of the upstream area is greater than a midstream fin wavelength of the midstream area, and a downstream fin wavelength of the downstream area is greater than the midstream fin wavelength of the midstream area.

### FIELD OF THE DISCLOSURE

The present disclosure relates to a liquid-cooling heat dissipation plate, and more particularly to a liquid-cooling heat dissipation plate having wavy fins.

### BACKGROUND OF THE DISCLOSURE

Coolers are widely used in various products. Generally, high-end products adopt water/liquid-cooling coolers for having advantages of quietness and stable cooling performance (as compared with air-cooling coolers). However, as an operating speed of chips of a power module in an electric vehicle increases, existing liquid-cooling coolers can no longer satisfy the heat dissipation requirements of these chips of the power module in the electric vehicle. Therefore, how to achieve heat dissipation more effectively via the liquid-cooling heat dissipation technology has long been an issue to be solved in the relevant industry.

### SUMMARY OF THE DISCLOSURE

In response to the above-referenced technical inadequacy, the present disclosure provides a liquid-cooling heat dissipation plate having wavy fins.

In order to solve the above-mentioned problem, one of the technical aspects adopted by the present disclosure is to provide a liquid-cooling heat dissipation plate. The liquid-cooling heat dissipation plate is disposed in a closed-loop liquid-cooling cooler, and includes a heat dissipation plate body and a plurality of wavy fins. The heat dissipation plate body has a first heat dissipation surface and a second heat dissipation surface that are opposite to each other, the first heat dissipation surface is configured to be in contact with a plurality of chips, and the second heat dissipation surface is configured to be in contact with a cooling liquid. The wavy fins are formed on the second heat dissipation surface of the heat dissipation plate body, the heat dissipation plate body is divided to have a first heat dissipation area to an N-th heat dissipation area according to a cooling-liquid flowing direction, and N is an integer greater than or equal to three. A fin pitch of the (N−2)-th heat dissipation area is greater than or equal to a fin pitch of the (N−1)-th heat dissipation area, the fin pitch of the (N−1)-th heat dissipation area is greater than or equal to a fin pitch of the N-th heat dissipation area, and the fin pitch of the (N−2)-th heat dissipation area is greater than the fin pitch of the N-th heat dissipation area. Each of the heat dissipation areas is divided into an upstream area, a midstream area, and a downstream area according to the cooling-liquid flowing direction, an upstream fin wavelength of the upstream area is greater than a midstream fin wavelength of the midstream area, and a downstream fin wavelength of the downstream area is greater than the midstream fin wavelength of the midstream area.

In one of the possible or preferred embodiments, the upstream fin wavelength of the upstream area in each of the heat dissipation areas is controlled to be between a first upstream wavelength and a second upstream wavelength, the midstream fin wavelength of the midstream area in each of the heat dissipation areas is controlled to be between a first midstream wavelength and a second midstream wavelength, the downstream fin wavelength of the downstream area in each of the heat dissipation areas is controlled to be between a first downstream wavelength and a second downstream wavelength, and a fin amplitude in each of the heat dissipation areas is controlled to be between a first amplitude and a second amplitude.

In one of the possible or preferred embodiments, when the upstream fin wavelength of the upstream area, the midstream fin wavelength of the midstream area, and the downstream fin wavelength of the downstream area in each of the heat dissipation areas are respectively controlled to be the first upstream wavelength, the first midstream wavelength, and the first downstream wavelength, the fin amplitude in each of the heat dissipation areas is controlled to be the second amplitude. When the upstream fin wavelength of the upstream area, the midstream fin wavelength of the midstream area, and the downstream fin wavelength of the downstream area in each of the heat dissipation areas are respectively controlled to be the second upstream wavelength, the second midstream wavelength, and the second downstream wavelength, the fin amplitude in each of the heat dissipation areas is controlled to be the first amplitude.

In one of the possible or preferred embodiments, the heat dissipation plate body is made of one of copper, a copper alloy, aluminum, and an aluminum alloy.

In one of the possible or preferred embodiments, the heat dissipation plate body is integrally formed by metal injection molding.

In one of the possible or preferred embodiments, the heat dissipation plate body is integrally formed by forging.

In one of the possible or preferred embodiments, a width of the wavy fin ranges between 0.8 mm and 5 mm.

In one of the possible or preferred embodiments, an included angle of the wavy fin ranges between 100° and 150°.

In one of the possible or preferred embodiments, a draft angle of the wavy fin ranges between 0° and 5°.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a liquid-cooling heat dissipation plate according to the present disclosure;

FIG. 2 is a schematic bottom view of the liquid-cooling heat dissipation plate according to the present disclosure;

FIG. 3 is a schematic view showing a heat dissipation area of the liquid-cooling heat dissipation plate according to the present disclosure; and

FIG. 4 is a schematic view showing a draft angle of a fin of the liquid-cooling heat dissipation plate according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

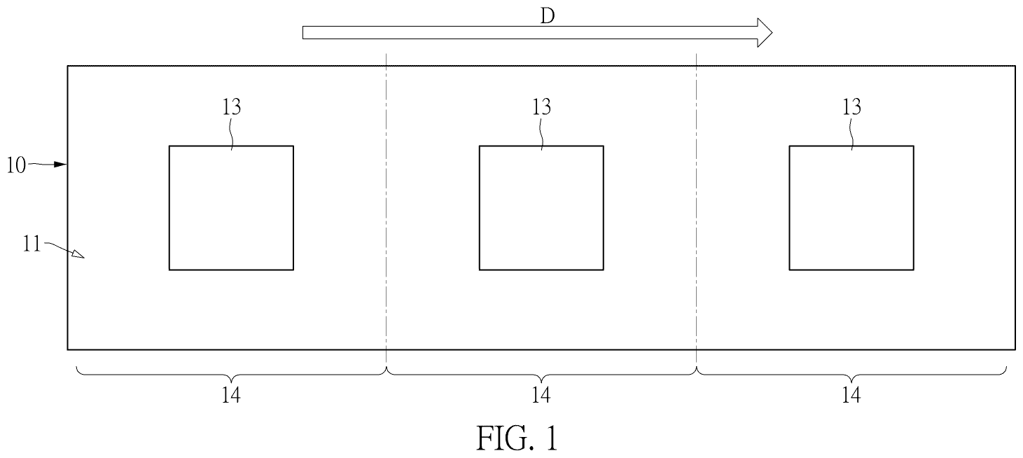

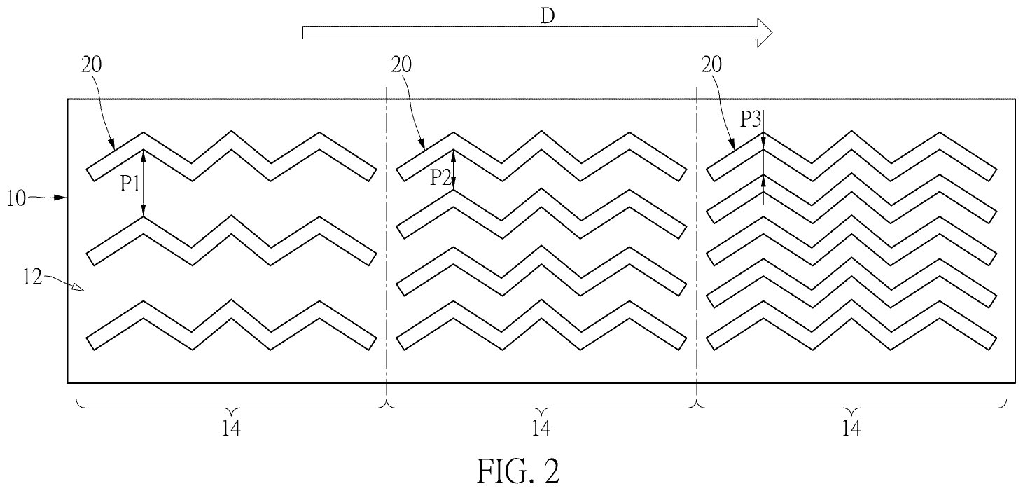

Referring to FIG. 1 to FIG. 4, an embodiment of the present disclosure provides a liquid-cooling heat dissipation plate having wavy fins. The liquid-cooling heat dissipation plate is disposed in a closed-loop liquid-cooling cooler, and there is no limitation on the configuration of the closed-loop liquid-cooling cooler. As shown in FIG. 1 and FIG. 2, the liquid-cooling heat dissipation plate provided in the embodiment of the present disclosure essentially includes a heat dissipation plate body 10 and a plurality of wavy fins 20.

In the present embodiment, the heat dissipation plate body 10 is made of a high thermal conductive material, such as copper, a copper alloy, aluminum, and an aluminum alloy. In addition, the heat dissipation plate body 10 has a first heat dissipation surface 11 and a second heat dissipation surface 12 that are opposite to each other. The first heat dissipation surface 11 is configured to be in contact with a plurality of chips 13. The second heat dissipation surface 12 is configured to be in contact with a cooling liquid, such as water or ethylene glycol (not shown in the figures). The chip 13 of the present embodiment can be a power chip of a power module in an electric vehicle.

In the present embodiment, the wavy fins 20 are formed on the second heat dissipation surface 12 of the heat dissipation plate body 10. The wavy fins 20 can be integrally formed on the second heat dissipation surface 12 of the heat dissipation plate body 10. Specifically, the wavy fins 20 and the heat dissipation plate body 10 can be integrally formed by metal injection molding (MIM), thereby having material continuity. The heat dissipation plate body 10 can also be integrally formed by forging.

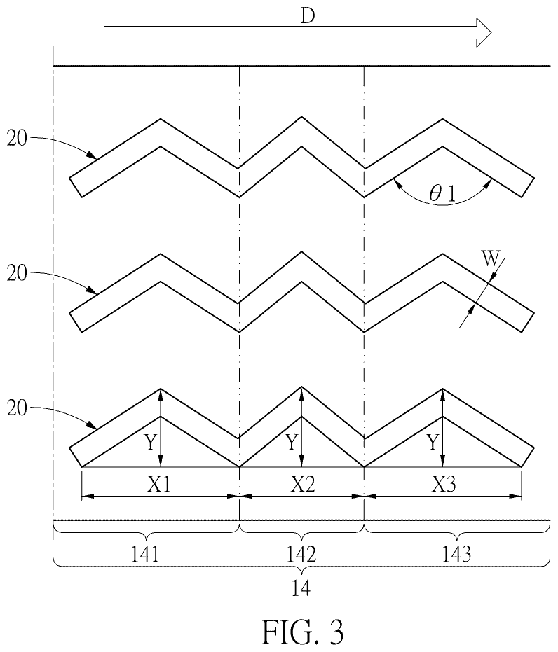

In the present embodiment, the heat dissipation plate body 10 is divided to have a first to an N-th heat dissipation area 14 according to a cooling-liquid flowing direction D (as shown in FIG. 1 and FIG. 2), and N is an integer greater than or equal to three. The chips 13 correspond in position to the first to the N-th heat dissipation area 14, respectively. A fin pitch P1 of the first (i.e., N−2) heat dissipation area 14 is greater than or equal to a fin pitch P2 of the second (i.e., N−1) heat dissipation area 14, the fin pitch P2 of the second (i.e., N−1) heat dissipation area 14 is greater than or equal to a fin pitch P3 of the third (i.e., N) heat dissipation area 14, and the fin pitch P1 of the first (i.e., N−2) heat dissipation area 14 is required to be greater than the fin pitch P3 of the third (i.e., N) heat dissipation area 14. As shown in FIG. 3, each heat dissipation area 14 is divided into an upstream area 141, a midstream area 142, and a downstream area 143 according to the cooling-liquid flowing direction D. An upstream fin wavelength X1 of the upstream area 141 is greater than a midstream fin wavelength X2 of the midstream area 142, and a downstream fin wavelength X3 of the downstream area 143 is also greater than the midstream fin wavelength X2 of the midstream area 142. In this way, along the cooling-liquid flowing direction D, a flow velocity of the cooling liquid that travels through the (N−2)-th heat dissipation area 14 is far greater than that of the cooling liquid that travels through the N-th heat dissipation area 14. Furthermore, along the cooling-liquid flowing direction D, the flow velocity of the cooling liquid that travels through the upstream area 141 and the downstream area 143 in each heat dissipation area 14 can be increased to quickly remove high heat, thereby simultaneously achieving uniformity of an overall heat dissipation temperature and reduction of an overall pressure drop.

More specifically, in order to achieve the overall pressure drop and the heat dissipation performance as required, the upstream fin wavelength X1 of the upstream area 141 in each heat dissipation area 14 is controlled to be between a first upstream wavelength (2.2 mm) and a second upstream wavelength (3.5 mm), the midstream fin wavelength X2 of the midstream area 142 in each heat dissipation area 14 is controlled to be between a first midstream wavelength (1 mm) and a second midstream wavelength (2.19 mm), the downstream fin wavelength X3 of the downstream area 143 in each heat dissipation area 14 is controlled to be between a first downstream wavelength (2.2 mm) and a second downstream wavelength (3.5 mm), and a fin amplitude Y in each heat dissipation area 14 is controlled to be between a first amplitude (1.1 mm) and a second amplitude (1.7 mm). When the upstream fin wavelength X1 of the upstream area 141, the midstream fin wavelength X2 of the midstream area 142, and the downstream fin wavelength X3 of the downstream area 143 in each heat dissipation area 14 are respectively controlled to be the first upstream wavelength, the first midstream wavelength, and the first downstream wavelength, the fin amplitude Y in each heat dissipation area 14 is controlled to be the second amplitude. When the upstream fin wavelength X1 of the upstream area 141, the midstream fin wavelength X2 of the midstream area 142, and the downstream fin wavelength X3 of the downstream area 143 in each heat dissipation area 14 are respectively controlled to be the second upstream wavelength, the second midstream wavelength, and the second downstream wavelength, the fin amplitude Y in each heat dissipation area 14 is controlled to be the first amplitude. That is to say, when fin wavelengths of the upstream area 141, the midstream area 142, and the downstream area 143 are each controlled to be short, fin amplitudes of the upstream area 141, the midstream area 142, and the downstream area 143 are each controlled to be large. Conversely, when the fin wavelengths of the upstream area 141, the midstream area 142, and the downstream area 143 are each controlled to be long, the fin amplitudes of the upstream area 141, the midstream area 142, and the downstream area 143 are each controlled to be small. By adjusting the wavelength and the amplitude, the overall pressure drop and the heat dissipation performance as required can be achieved.

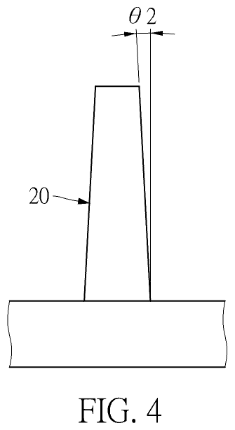

In the present embodiment, a width W of the wavy fin 20 (as shown in FIG. 3) preferably ranges between 0.8 mm and 5 mm, an included angle θ1 of the wavy fin 20 preferably ranges between 100° and 150°, and a draft angle θ2 of the wavy fin 20 (as shown in FIG. 4) preferably ranges between 0° and 5°.

### Beneficial Effects of the Embodiment

In conclusion, the liquid-cooling heat dissipation plate provided by the present disclosure is disposed in a closed-loop liquid-cooling cooler, and includes a heat dissipation plate body and a plurality of wavy fins. The heat dissipation plate body has a first heat dissipation surface and a second heat dissipation surface that are opposite to each other, the first heat dissipation surface is configured to be in contact with a plurality of chips, and the second heat dissipation surface is configured to be in contact with a cooling liquid. The wavy fins are formed on the second heat dissipation surface. The heat dissipation plate body is divided to have a plurality of heat dissipation areas according to a cooling-liquid flowing direction. A fin pitch of a first heat dissipation area is greater than or equal to a fin pitch of a second heat dissipation area, the fin pitch of the second heat dissipation area is greater than or equal to a fin pitch of a third heat dissipation area, and the fin pitch of the first heat dissipation area is greater than the fin pitch of the third heat dissipation area. In addition, each heat dissipation area is divided into an upstream area, a midstream area, and a downstream area according to the cooling-liquid flowing direction. An upstream fin wavelength of the upstream area is greater than a midstream fin wavelength of the midstream area, and a downstream fin wavelength of the downstream area is greater than the midstream fin wavelength of the midstream area. In this way, along the cooling-liquid flowing direction, a flow velocity of the cooling liquid that travels through the first heat dissipation area is far greater than that of the cooling liquid that travels through the third heat dissipation area. Furthermore, along the cooling-liquid flowing direction, the flow velocity of the cooling liquid that travels through the upstream area and the downstream area in each heat dissipation area can be increased to quickly remove high heat, thereby simultaneously achieving uniformity of an overall heat dissipation temperature and reduction of an overall pressure drop.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid-cooling heat dissipation plate, which is disposed in a closed-loop liquid-cooling cooler, comprising:
a heat dissipation plate body; and
a plurality of wavy fins;
wherein the heat dissipation plate body has a first heat dissipation surface and a second heat dissipation surface that are opposite to each other, the first heat dissipation surface is configured to be in contact with a plurality of chips, and the second heat dissipation surface is configured to be in contact with a cooling liquid; wherein the wavy fins are formed on the second heat dissipation surface of the heat dissipation plate body, the heat dissipation plate body is divided to have a first heat dissipation area to an N-th heat dissipation area according to a cooling-liquid flowing direction, and N is an integer greater than or equal to three; wherein a fin pitch of the (N−2)-th heat dissipation area is greater than or equal to a fin pitch of the (N−1)-th heat dissipation area, the fin pitch of the (N−1)-th heat dissipation area is greater than or equal to a fin pitch of the N-th heat dissipation area, and the fin pitch of the (N−2)-th heat dissipation area is greater than the fin pitch of the N-th heat dissipation area; wherein each of the heat dissipation areas is divided into an upstream area, a midstream area, and a downstream area according to the cooling-liquid flowing direction, an upstream fin wavelength of the upstream area is greater than a midstream fin wavelength of the midstream area, and a downstream fin wavelength of the downstream area is greater than the midstream fin wavelength of the midstream area.

2. The liquid-cooling heat dissipation plate according to claim 1, wherein the upstream fin wavelength of the upstream area in each of the heat dissipation areas is controlled to be between a first upstream wavelength and a second upstream wavelength, the midstream fin wavelength of the midstream area in each of the heat dissipation areas is controlled to be between a first midstream wavelength and a second midstream wavelength, the downstream fin wavelength of the downstream area in each of the heat dissipation areas is controlled to be between a first downstream wavelength and a second downstream wavelength, and a fin amplitude in each of the heat dissipation areas is controlled to be between a first amplitude and a second amplitude.

3. The liquid-cooling heat dissipation plate according to claim 2, wherein, when the upstream fin wavelength of the upstream area, the midstream fin wavelength of the midstream area, and the downstream fin wavelength of the downstream area in each of the heat dissipation areas are respectively controlled to be the first upstream wavelength, the first midstream wavelength, and the first downstream wavelength, the fin amplitude in each of the heat dissipation areas is controlled to be the second amplitude; wherein, when the upstream fin wavelength of the upstream area, the midstream fin wavelength of the midstream area, and the downstream fin wavelength of the downstream area in each of the heat dissipation areas are respectively controlled to be the second upstream wavelength, the second midstream wavelength, and the second downstream wavelength, the fin amplitude in each of the heat dissipation areas is controlled to be the first amplitude.

4. The liquid-cooling heat dissipation plate according to claim 1, wherein the heat dissipation plate body is made of one of copper, a copper alloy, aluminum, and an aluminum alloy.

5. The liquid-cooling heat dissipation plate according to claim 1, wherein the heat dissipation plate body is integrally formed by metal injection molding.

6. The liquid-cooling heat dissipation plate according to claim 1, wherein the heat dissipation plate body is integrally formed by forging.

7. The liquid-cooling heat dissipation plate according to claim 1, wherein a width of the wavy fin ranges between 0.8 mm and 5 mm.

8. The liquid-cooling heat dissipation plate according to claim 1, wherein an included angle of the wavy fin ranges between 100° and 150°.

9. The liquid-cooling heat dissipation plate according to claim 1, wherein a draft angle of the wavy fin ranges between 0° and 5°.
